(19) United States
(12) Patent Application Publication
(10) Pub. No.: US 2024/0172475 A1
(43) Pub. Date: May 23, 2024

(54) ETCHING SOLUTION AND MANUFACTURING METHOD OF DISPLAY PANEL

(71) Applicant: HANNSTAR DISPLAY CORPORATION, Taipei City (TW)

(72) Inventors: Li-Fang Chiu, Tainan City (TW); Ching-Chieh Lee, Kaohsiung City (TW); Chien-Hung Wu, Tainan City (TW)

(73) Assignee: HANNSTAR DISPLAY CORPORATION, Taipei City (TW)

(21) Appl. No.: 18/381,169

(22) Filed: Oct. 17, 2023

(30) Foreign Application Priority Data
Nov. 18, 2022 (CN) 202211447162.0

(51) Int. Cl. H10K 59/12; C09K 13/04; H10K 71/20

(52) U.S. Cl. CPC H10K 59/1201; C09K 13/04; H10K 71/231

(57) ABSTRACT

The invention discloses an etching solution and a manufacturing method of a display panel. The method includes following steps: providing a first substrate; forming a conductive layer stack including a first sub-layer, a second sub-layer and a third sub-layer, each of the first sub-layer and the second sub-layer includes a transparent conductive material including indium-containing oxide, the third sub-layer is disposed between the first sub-layer and the second sub-layer, and the third sub-layer includes silver or silver alloy; performing an etching process, an etching solution is used to etch the first sub-layer, the second sub-layer and the third sub-layer to form a first patterned sub-layer, a second patterned sub-layer and a third patterned sub-layer, and the etching solution includes 1 to 2.6 wt % of nitric acid, 35 to 45 wt % of acetic acid, 35 to 45 wt % of phosphoric acid and a remaining amount of water.

### BACKGROUND OF THE INVENTION

### 1. Field of the Invention

The present invention relates to an etching solution and a manufacturing method of a display panel, and more particular to an etching solution and a manufacturing method of a display panel used for forming high-quality reflective electrodes in display panels.

### 2. Description of the Prior Art

Among different types of display panels, reflective display panels or transflective display panels have the advantage of low power consumption since the ambient light is utilized as the light source to achieve display effects in these display panels. Nowadays, many electronic products (such as tablets, electronic papers, tablet PCs, notebooks, etc.) have adopted reflective or transflective display panels, and improving the display quality of reflective or transflective display panels is one of the purposes in this invention.

### SUMMARY OF THE INVENTION

One of the purposes of the present invention is providing an etching solution and a manufacturing method of a display panel, and the technical problem to be solved is how to form high-quality reflective electrodes and improve the display quality of the display panel.

To solve the above technical problems, the present invention provides a manufacturing method of a display panel which includes following steps: providing a first substrate; forming a conductive layer stack on the first substrate, the conductive layer stack includes a first sub-layer, a second sub-layer and a third sub-layer, the second sub-layer is disposed on the first sub-layer, a material of each of the first sub-layer and the second sub-layer includes a transparent conductive material, the transparent conductive material includes an indium-containing oxide, the third sub-layer is disposed between the first sub-layer and the second sub-layer, and a material of the third sub-layer includes silver or silver alloy; forming a photoresist pattern on the conductive layer stack; and performing an etching process on the conductive layer stack, an etching solution is used in the etching process to etch the first sub-layer, the second sub-layer and the third sub-layer to form a first patterned sub-layer, a second patterned sub-layer and a third patterned sub-layer, and the etching solution includes 1 to 2.6 wt % of nitric acid, 35 to 45 wt % of acetic acid, 35 to 45 wt % of phosphoric acid and a remaining amount of water.

To solve the above technical problems, the present invention also provides an etching solution which is used for performing an etching process on a conductive layer stack of a display panel to form a patterned conductive layer stack, and the etching solution includes 1 to 2.6 wt % of nitric acid, 35 to 45 wt % of acetic acid, 35 to 45 wt % of phosphoric acid and a remaining amount of water. The conductive layer stack includes a first sub-layer, a second sub-layer and a third sub-layer, the third sub-layer is disposed between the first sub-layer and the second sub-layer, the patterned conductive layer stack includes a first patterned sub-layer, a second patterned sub-layer and a third patterned sub-layer, and the third patterned sub-layer is disposed between the first patterned sub-layer and the second patterned sub-layer. The etching solution is used in the etching process to etch the first sub-layer, the second sub-layer and the third sub-layer to form the first patterned sub-layer, the second patterned sub-layer and the third patterned sub-layer. Each of the first sub-layer, the second sub-layer, the first patterned sub-layer and the second patterned sub-layer includes a transparent conductive material including an indium-containing oxide, and each of the third sub-layer and the third patterned sub-layer includes silver or silver alloy.

In the manufacturing method of the display panel of the present invention, the etching solution can be used to etch the conductive layer stack to form the reflective electrode. The etching process is one-step etching, and the etching process etches the first, second and third sub-layers together to form the patterned conductive layer stack. Through the etching process of the present invention, the damage of the edge of the silver layer of the patterned conductive layer stack can be effectively suppressed, and the silver residues on the edge of the patterned conductive layer stack can also be effectively suppressed, and these can improve the reflection effect of the reflective electrode and further improve the display quality of the display panel.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a step of forming a conductive layer stack in a manufacturing method of a display panel according to a first embodiment of the present invention.

FIG. 2 is a schematic diagram illustrating a step of forming a photoresist pattern and performing an etching process in the manufacturing method of the display panel according to the first embodiment of the present invention.

FIG. 3 is a schematic diagram illustrating forming a reflective electrode by three-step etching.

FIG. 4 is a partially enlarged schematic diagram illustrating a top view of the reflective electrodes formed by three-step etching.

FIG. 5 is a schematic diagram illustrating a step of forming a reflective electrode by one-step etching in the manufacturing method of the display panel according to the first embodiment of the present invention.

FIG. 6 is a partially enlarged schematic diagram illustrating a top view of the reflective electrodes formed by one-step etching in the manufacturing method of the display panel according to the first embodiment of the present invention.

FIG. 7 is a schematic diagram illustrating the steps of forming the first alignment layer and the remaining components in the manufacturing method of the display panel according to the first embodiment of the present invention.

FIG. 8 is a flowchart of the manufacturing method of the display panel according to the first embodiment of the present invention.

FIG. 9 and FIG. 10 are schematic diagrams of an example of forming the reflective electrode in the first embodiment of the present invention.

FIG. 11 is a schematic diagram illustrating a step of removing a second patterned sub-layer in a manufacturing method of a display panel according to a second embodiment of the present invention.

FIG. 12 is a schematic cross-sectional diagram illustrating the display panel according to the second embodiment of the present invention.

FIG. 13 is a schematic diagram illustrating a step of forming a photoresist pattern in a manufacturing method of a display panel according to a third embodiment of the present invention.

FIG. 14 and FIG. 15 are schematic diagrams of an example of forming a reflective electrode in the third embodiment of the present invention.

### DETAILED DESCRIPTION

To provide a better understanding of the present invention to those skilled in this field, preferred embodiments will be detailed as follows. The preferred embodiments of the present invention are illustrated in the accompanying drawings to elaborate on the contents and effects to be achieved. It should be noted that the drawings are simplified schematics, and therefore show only the components and combinations associated with the present invention, so as to provide a clearer description of the basic architecture or method of implementation. The components would be complex in reality. In addition, for ease of explanation, the components shown in the drawings may not represent their actual number, shape, and dimensions; details can be adjusted according to design requirements.

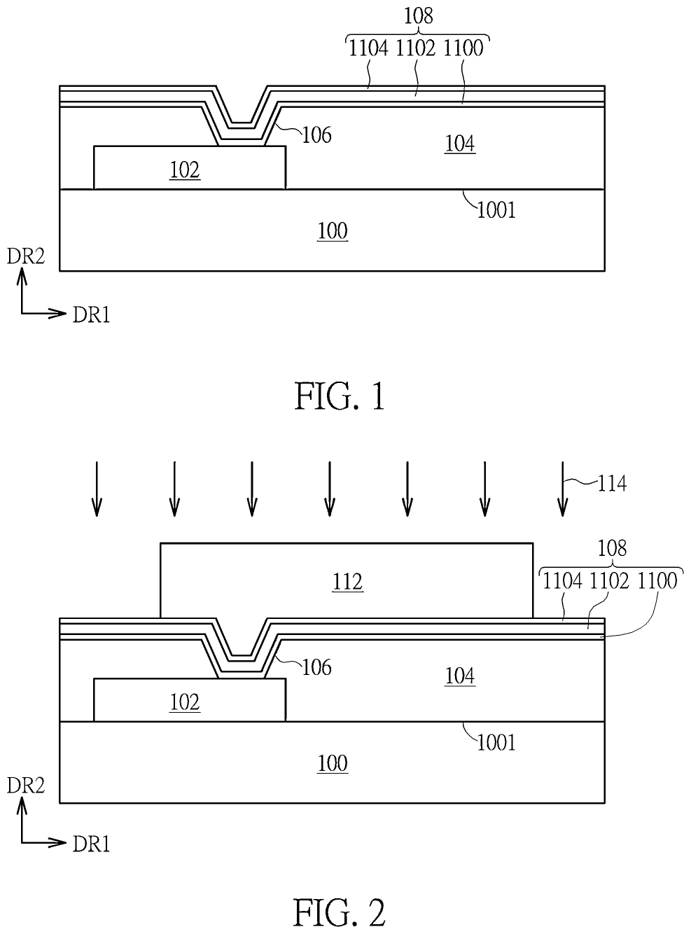

A direction DR1 and a direction DR2 are shown in the following drawings. The direction DR2 may be a normal direction or a top view direction, and the direction DR2 can be perpendicular to a top surface 1001 of a substrate 100 as shown in FIG. 1. The direction DR1 may be a horizontal direction and perpendicular to the direction DR2. As shown in FIG. 1, the direction DR1 can be parallel to the top surface 1001 of the substrate 100. The spatial relationship of structures can be described according to the directions DR1 and DR2 in the following drawings.

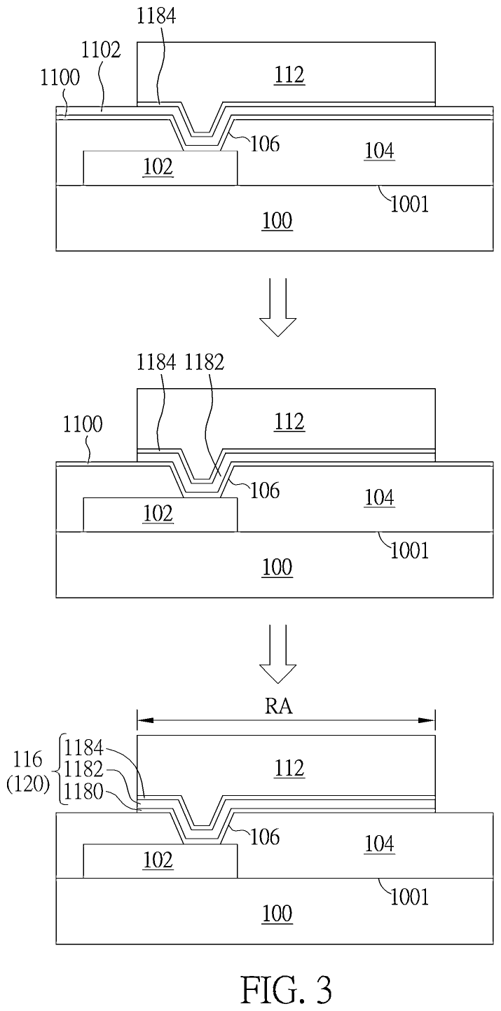

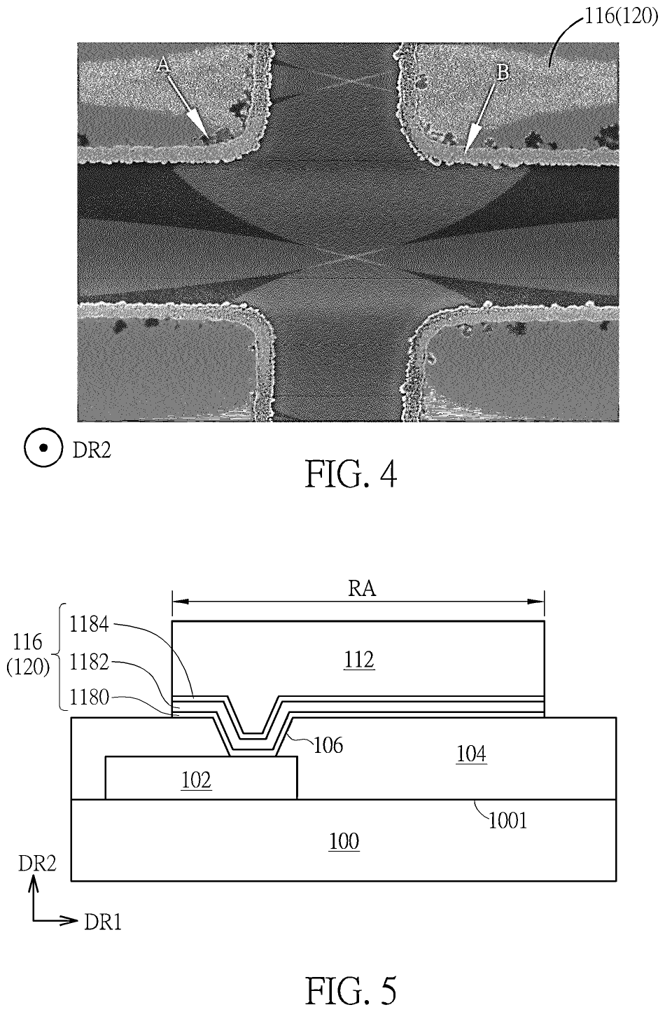

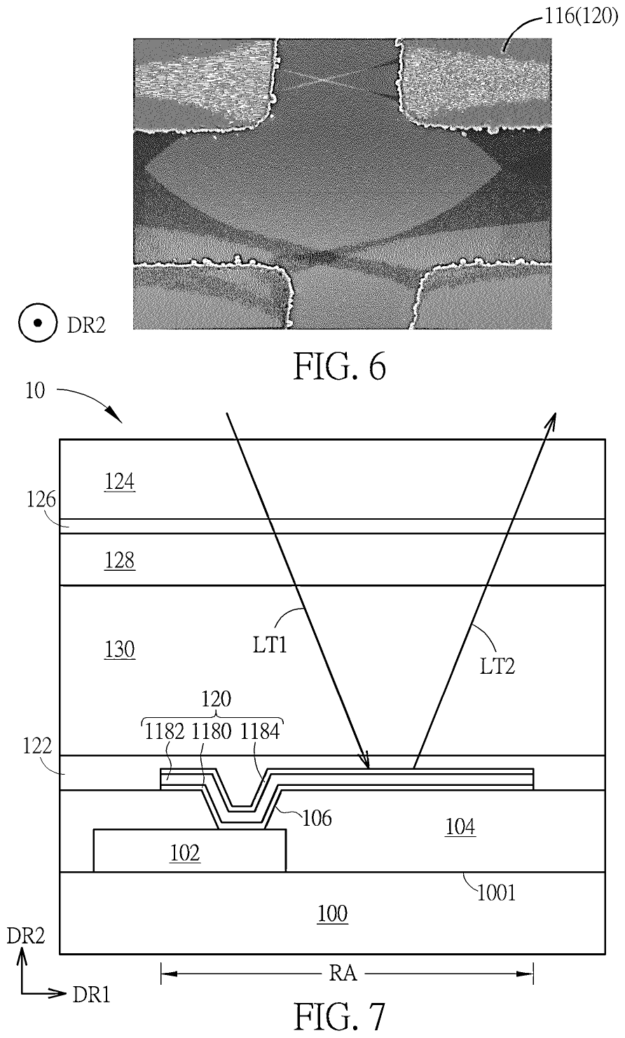

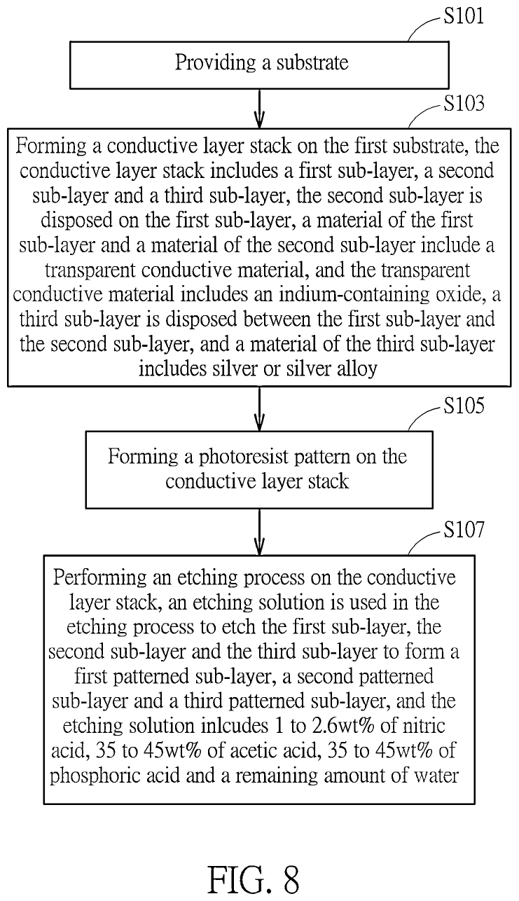

Referring to FIG. 1 to FIG. 8, FIG. 1 is a schematic diagram illustrating a step of forming a conductive layer stack in a manufacturing method of a display panel according to a first embodiment of the present invention, FIG. 2 is a schematic diagram illustrating a step of forming a photoresist pattern and performing an etching process in the manufacturing method of the display panel according to the first embodiment of the present invention, FIG. 3 is a schematic diagram illustrating forming a reflective electrode by three-step etching, FIG. 4 is a partially enlarged schematic diagram illustrating a top view of the reflective electrodes formed by three-step etching, FIG. 5 is a schematic diagram illustrating a step of forming a reflective electrode by one-step etching in the manufacturing method of the display panel according to the first embodiment of the present invention, FIG. 6 is a partially enlarged schematic diagram illustrating a top view of the reflective electrodes formed by one-step etching in the manufacturing method of the display panel according to the first embodiment of the present invention, FIG. 7 is a schematic diagram illustrating the steps of forming the first alignment layer and the remaining components in the manufacturing method of the display panel according to the first embodiment of the present invention, and FIG. 8 is a flowchart of the manufacturing method of the display panel according to the first embodiment of the present invention.

It should be understood that the steps shown in FIG. 8 may not be complete, and other steps may be performed before, after or between the shown steps. In addition, some steps may be performed simultaneously or in a different order from that shown in FIG. 8.

As shown in FIG. 1 and FIG. 8, a step S101 can be performed first to provide a substrate 100, and a thin film transistor 102 and an insulating layer 104 are formed on the substrate 100, and the insulating layer 104 covers the thin film transistor 102. The substrate 100 may include a rigid substrate such as a glass substrate, a plastic substrate, a quartz substrate or a sapphire substrate, but not limited thereto. The substrate 100 may also include a flexible substrate such as polyimide (PI) substrate or polyethylene terephthalate (PET) substrate, but not limited thereto. The insulating layer 104 may include an inorganic insulating material, an organic insulating material, or a combination of the above, but not limited thereto. The insulating layer 104 may include a single-layer structure or a multi-layer structure.

Next, a via hole 106 is formed in the insulating layer 104. Next, a step S103 can be performed to form a conductive layer stack 108. The conductive layer stack 108 is disposed on the insulating layer 104 and filled in the via hole 106, and the conductive layer stack 108 is electrically connected to the thin film transistor 102. The conductive layer stack 108 includes a first sub-layer 1100, a second sub-layer 1104 and a third sub-layer 1102. The second sub-layer 1104 is disposed on the first sub-layer 1100, and the third sub-layer 1102 is disposed between the first sub-layer 1100 and the second sub-layer 1104.

In this embodiment, the first sub-layer 1100 can be directly contacted with the third sub-layer 1102 (e.g., the top surface of the first sub-layer 1100 is directly contacted with the bottom surface of the third sub-layer 1102), and the third sub-layer 1102 can be directly contacted with the second sub-layer 1104 (e.g., the bottom surface of the second sub-layer 1104 is directly contacted with the top surface of the third sub-layer 1102), but not limited thereto. The first sub-layer 1100 and the second sub-layer 1104 may be transparent conductive layers, and the third sub-layer 1102 may be a metal layer. The conductive layer stack 108 can be formed by sequentially forming the first sub-layer 1100, the third sub-layer 1102 and the second sub-layer 1104 on the insulating layer 104. The conductive layer stack 108 can be electrically connected to the thin film transistor 102 through the via hole 106.

The material of each of the first sub-layer 1100 and the second sub-layer 1104 may include a transparent conductive material, and the transparent conductive material may include indium-containing oxide. For example, the indium-containing oxide may include indium tin oxide (ITO) or indium zinc oxide (IZO), but not limited thereto. The material of the first sub-layer 1100 and the material of the second sub-layer 1104 may be the same or different. For example, the material of the first sub-layer 1100 and the material of the second sub-layer 1104 may both include indium tin oxide or indium zinc oxide, or one of the first and second sub-layers 1100 and 1104 may include indium tin oxide, and the other one of the first and second sub-layers 1100 and 1104 may include indium zinc oxide. The material of the third sub-layer 1102 may include metal, such as silver or silver alloy, but not limited thereto.

Since the third sub-layer 1102 is the metal layer, the adhesion between the metal layer and the insulating layer 104 may be poor and easy to peel off. Therefore, in this embodiment, the first sub-layer 1100 is further disposed between the third sub-layer 1102 and the insulating layer 104, the first sub-layer 1100 is the transparent conductive layer, and the first sub-layer 1100 is directly contacted with the insulating layer 104 (e.g., the bottom surface of the first sub-layer 1100 is directly contacted with the insulating layer 104) to prevent the third sub-layer 1102 from peeling off.

In addition, since the material of the third sub-layer 1102 may include metal, the surface of the third sub-layer 1102 will react with external substances during the time waiting for performing the subsequent process (such as the period after the conductive layer stack 108 is formed and before the patterning process of the conductive layer stack 108 is performed) and/or during the subsequent process (such as during the patterning process of the conductive layer stack 108) if the conductive layer stack 108 does not include the layer (such as the second sub-layer 1104) covering the third sub-layer 1102.

Taking the embodiment in which the material of the third sub-layer 1102 includes silver or silver alloy as an example, silver is easy to react with external substances and cause the change in color and/or reflectivity reduction. Therefore, in the process of forming the conductive layer stack 108 and after the third sub-layer 1102 is formed, the second sub-layer 1104 including transparent conductive material is formed on the third sub-layer 1102, the second sub-layer 1104 can protect the third sub-layer 1102 and prevent the third sub-layer 1102 from reacting with external substances during the time waiting for performing the subsequent process and/or during the subsequent process.

Next, as shown in FIG. 2, a step S105 can be performed to form a photoresist pattern 112 on the conductive layer stack 108. The photoresist pattern 112 covers a portion of the conductive layer stack 108 and overlaps the via hole 106.

Next, a step S107 can be performed to perform an etching process 114 on the conductive layer stack 108 through the photoresist pattern 112, and an etching solution is used in the etching process 114 to etch the first sub-layer 1100, the second sub-layer 1104 and the third sub-layer 1102 to form a patterned conductive layer stack 116 (shown in FIG. 3 and FIG. 5).

Next, a comparison of forming the patterned conductive layer stack 116 by two different etching processes 114 (e.g., three-step etching process in FIG. 3 and FIG. 4 and one-step etching process in FIG. 5 and FIG. 6) in the present invention will be explained.

As shown in FIG. 3 and from top to bottom of FIG. 3, in the first type of etching process, the first sub-layer 1100, the second sub-layer 1104 and the third sub-layer 1102 can be etched through three etching steps respectively. As shown in the top figure in FIG. 3, the second sub-layer 1104 can be etched to form a second patterned sub-layer 1184 first. Next, as shown in the middle figure in FIG. 3, the third sub-layer 1102 can be etched to form a third patterned sub-layer 1182. Next, as shown in the bottom figure in FIG. 3, the first sub-layer 1100 can be etched to form a first patterned sub-layer 1180.

For example, the etching solution used in the step of etching the third sub-layer 1102 in the three etching steps can be different from the etching solutions used in the step of etching the first sub-layer 1100 and the step of etching the second sub-layer 1104 in the three etching steps, but not limited thereto. As shown in FIG. 3, the patterned conductive layer stack 116 includes the first patterned sub-layer 1180, the second patterned sub-layer 1184 and the third patterned sub-layer 1182. In this embodiment, the patterned conductive layer stack 116 is disposed in a reflective area RA of the display panel and used as a reflective electrode 120, but not limited thereto.

As shown in FIG. 4, FIG. 4 is a partially enlarged top view of the reflective electrodes 120 formed after the etching process of FIG. 3, and the gray part in FIG. 4 is a partially enlarged top view of the etched reflective electrodes 120. Specifically, four gray parts in the lower left, upper left, upper right and lower right in FIG. 4 respectively are partially enlarged top views of the reflective electrodes 120 of four pixels (or four sub-pixels) disposed at the lower left, upper left, upper right and lower right. In addition, the first patterned sub-layer 1180, the third patterned sub-layer 1182 and the second patterned sub-layer 1184 of the reflective electrode 120 in FIG. 4 respectively include indium tin oxide, silver and indium tin oxide.

After the first sub-layer 1100, the second sub-layer 1104 and the third sub-layer 1102 are etched through the three etching steps respectively in the etching process 114 to form the patterned conductive layer stack 116, some portions in the third patterned sub-layer 1182 (i.e. the silver layer) near the edge of the third patterned sub-layer 1182 may be damaged (as indicated by arrow A), or the edge of the patterned conductive layer stack 116 may have silver residues (as indicated by arrow B), and these may cause the reflection effect of the reflective electrodes 120 decrease, thereby decreasing the display quality of the display panel.

In order to solve the shortcomings of the first type of etching process, the inventors made experiments of various etching solutions with different composition ratios, and the preferred etching solution used for etching the first sub-layer 1100, the second sub-layer 1104 and the third sub-layer 1102 is obtained. The reflective electrode 120 formed by etching the first sub-layer 1100, the second sub-layer 1104 and the third sub-layer 1102 with the above etching solution does not have the problems of the damage of the edge of the silver layer and the silver residues caused by the first type of etching process (i.e., etching the first sub-layer 1100, the second sub-layer 1104 and the third sub-layer 1102 through three etching steps respectively). Next, the etching solution and etching method used in the second type of etching process will be described in detail (as shown in FIG. 5 and FIG. 6).

In the second type of etching process (as shown in FIG. 2 and FIG. 5), the present invention provides an etching solution which can be used to etch the first sub-layer 1100, the second sub-layer 1104 and the third sub-layer 1102 of the conductive layer stack 108 to form the first patterned sub-layer 1180, the second patterned sub-layer 1184 and the third patterned sub-layer 1182. The first patterned sub-layer 1180 and the second patterned sub-layer 1184 include the indium-containing oxide (such as indium tin oxide or indium zinc oxide), and the third patterned sub-layer 1182 includes silver or silver alloy.

The etching solution includes 1 to 2.6 wt % of nitric acid, 35 to 45 wt % of acetic acid, 35 to 45 wt % of phosphoric acid and the remaining amount of water based on the total weight of the etching solution. The etching solution of the present invention only includes nitric acid, acetic acid, phosphoric acid and water, and no other components are added, that is, the etching solution of the present invention is composed of nitric acid, acetic acid, phosphoric acid and water.

The water used in the etching solution may be deionized water. In addition, the temperature of the etching solution used in the etching process 114 is greater than or equal to 26° C. and less than or equal to 40° C. In the present invention, the etching solution used in the etching process 114 in FIG. 2 etches each of the first sub-layer 1100, the second sub-layer 1104 and the third sub-layer 1102 to form the first patterned sub-layer 1180, the second patterned sub-layer 1184 and the third patterned sub-layer 182 in FIG. 5, and therefore the etching process 114 is a one-step etching.

For example, the etching solution used in the etching process 114 in some embodiments may include 1.8 wt % of nitric acid, 40 wt % of acetic acid, 40 wt % of phosphoric acid, and the etching solution also includes the remaining amount of water, but not limited thereto. Additionally, in some embodiments, the temperature of the etching solution may be 35° C., but not limited thereto.

In this embodiment, the above-mentioned etching solution can be coated on the conductive layer stack 108 and the photoresist pattern 112 of FIG. 2 by an etching machine in the etching process 114 for example. A portion of the conductive layer stack 108 not covered by the photoresist pattern 112 is etched and removed by the above-mentioned etching solution. Another portion of the conductive layer stack 108 covered by the photoresist pattern 112 is not removed and remains to form the patterned conductive layer stack 116. However, the etching method of the etching process 114 of the present invention is not limited thereto.

In particular, in the etching solution of the present invention, the proportion range of acetic acid in the etching solution is increased to be the same as the proportion range of phosphoric acid in the etching solution, that is, the proportion range of acetic acid and the proportion range of phosphoric acid in the etching solution are both 35-45 wt %, while the proportion range of nitric acid in the etching solution is reduced to 1-2.6 wt %. Therefore, the etching uniformity can be improved to improve the flatness of the edge of the reflective electrode 120 formed after etching, thereby improving the display quality of the display panel.

In addition, the etching solution of the present invention can be composed of nitric acid, acetic acid, phosphoric acid and water without adding other components, thus the preparation of the etching solution can be simplified. In the production, it is only necessary to monitor whether the contents of nitric acid, acetic acid and phosphoric acid in the etching solution meet the standards, thus reducing the production monitoring cost.

As shown in FIG. 6, the gray part is a partially enlarged top view of the etched reflective electrode 120. In addition, the first patterned sub-layer 1180, the third patterned sub-layer 1182 and the second patterned sub-layer 1184 of the reflective electrode 120 in FIG. 6 respectively include indium tin oxide, silver and indium tin oxide. When the etching solution of the present invention is used in the etching process 114 to etch the first sub-layer 1100, the second sub-layer 1104 and the third sub-layer 1102 in one step to form the reflective electrode 120, the edge of the reflective electrode 120 does not have the phenomenon of damage of silver layer and silver residues, and therefore the reflective effect of the reflective electrode 120 is improved and the display quality of the display panel is further improved.

In summary, the present invention adopts the aforementioned second type of etching process as the etching process 114 in step the S107 of the manufacturing method of the display panel of the first embodiment of the present invention, and the present invention provides an etching solution including 1 to 2.6 wt % of nitric acid, 35 to 45 wt % of acetic acid, 35 to 45 wt % of phosphoric acid and the remaining amount of water. The etching process 114 uses the above-mentioned etching solution and the temperature of the etching solution is greater than or equal to 26° C. and less than or equal to 40° C. In the etching process 114, the first sub-layer 1100, the second sub-layer 1104 and the third sub-layer 1102 are etched by the above-mentioned etching solution to form the first patterned sub-layer 1180, the second patterned sub-layer 1184 and the third patterned sub-layer 1182. The first patterned sub-layer 1180 and the second patterned sub-layer 1184 include the indium-containing oxide (such as indium tin oxide or indium zinc oxide) and the third patterned sub-layer 1182 includes silver or silver alloy. Therefore, the etching process 114 in the step S107 of the manufacturing method of the display panel of the first embodiment of the present invention is the one-step etching process.

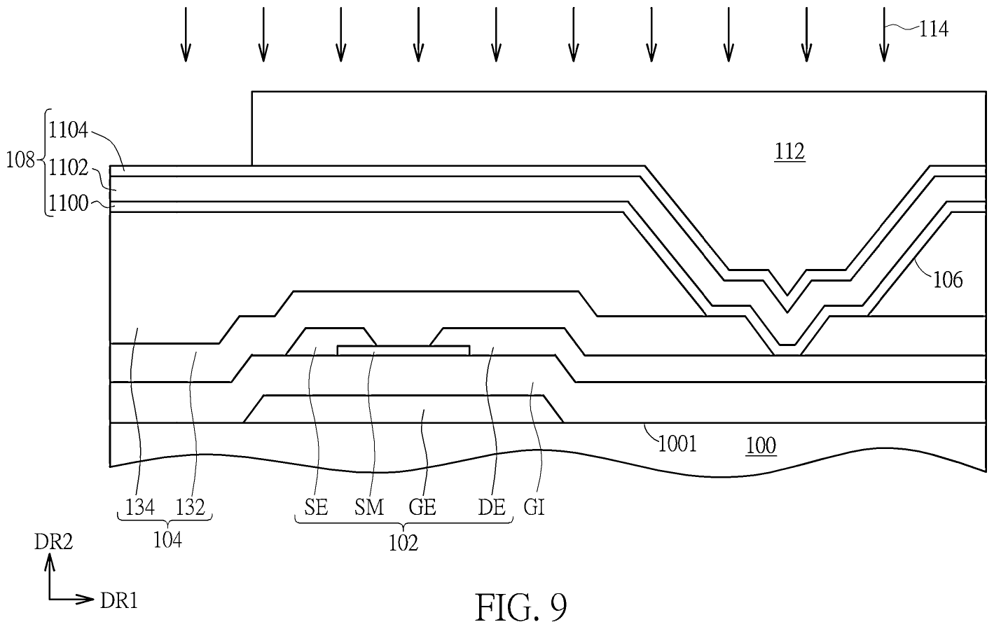

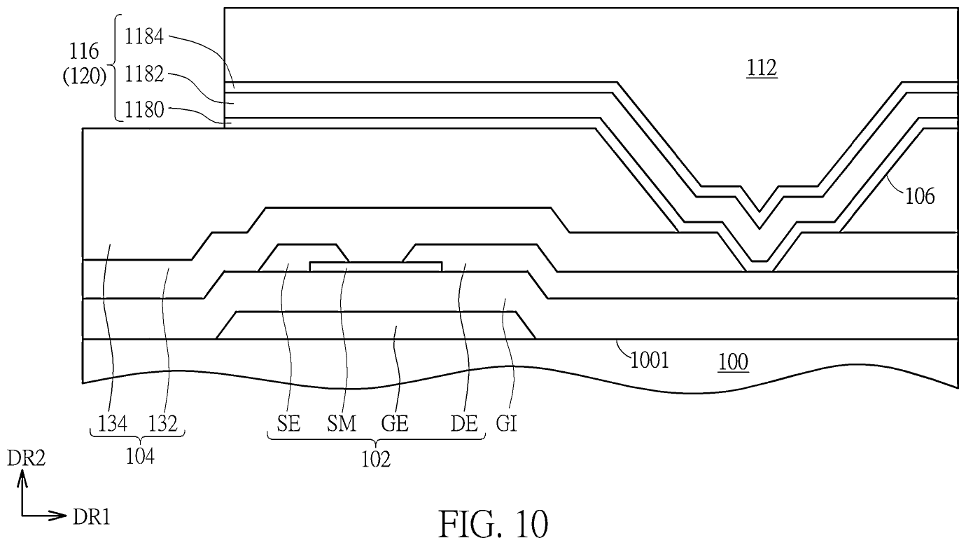

Referring to FIG. 9 and FIG. 10, FIG. 9 corresponds to FIG. 2 and FIG. 10 corresponds to FIG. 5. The thin film transistor 102 in FIG. 2 and FIG. 5 is illustrated as a bottom gate thin film transistor in FIG. 9 and FIG. 10 as an example, but not limited thereto. In other embodiments, the thin film transistor 102 in FIG. 2 and FIG. 5 may be a top gate thin film transistor. As shown in FIG. 9, the thin film transistor 102 includes a gate GE, a semiconductor layer SM, a source SE and a drain DE. The gate GE is disposed on the substrate 100, the semiconductor layer SM is disposed on the gate GE, and a gate insulating layer GI is disposed between the gate GE and the semiconductor layer SM. The source SE and drain DE are disposed on the gate insulating layer GI and on two sides of the semiconductor layer SM.

The gate GE, the source SE and the drain DE include conductive materials such as metal, but not limited thereto. The semiconductor layer SM includes a semiconductor material such as amorphous silicon, polysilicon or metal oxide, but not limited thereto.

The insulating layer 104 may include a multi-layer structure. For example, the insulating layer 104 may include an insulating layer 132 and an insulating layer 134, but not limited thereto. The insulating layer 132 is disposed on the source SE and the drain DE, and the insulating layer 134 is disposed on the insulating layer 132. The gate insulating layer GI, the insulating layer 132, and the insulating layer 134 may include inorganic insulating materials, organic insulating materials or a combination of the above, but not limited thereto. For example, the insulating layer 132 may include an inorganic insulating material, and the insulating layer 134 may include an organic insulating material and may be used as a planarization layer, but not limited thereto. The thickness of the insulating layer 134 may be greater than the thickness of the gate insulating layer GI and the thickness of the insulating layer 132, but not limited thereto.

The via hole 106 can penetrate through the insulating layer 134 and the insulating layer 132 and expose a portion of the surface of the drain DE, and the conductive layer stack 108 can be filled in the via hole 106 and electrically connected to the drain DE. For example, the first sub-layer 1100 in the conductive layer stack 108 may contact the drain DE. Next, the etching process 114 is performed to obtain the reflective electrode 120 shown in FIG. 10.

Next, as shown in FIG. 7, a first alignment layer 122 is formed on the reflective electrode 120. The first alignment layer 122 can cover the reflective electrode 120 and the insulating layer 104, and the first alignment layer 122 is directly contacted with the second patterned sub-layer 1184.

In addition, a substrate 124 is provided, a common electrode 126 and a second alignment layer 128 are formed on the substrate 124, and the common electrode 126 is disposed between the substrate 124 and the second alignment layer 128. The substrate 124 may include a rigid or flexible transparent substrate, but not limited thereto. The common electrode 126 may include a transparent conductive material, but not limited thereto.

Next, the substrate 100 and the substrate 124 are assembled, and a liquid crystal layer 130 is disposed between the substrate 100 and the substrate 124 to form the display panel 10. FIG. 1 to FIG. 7 and FIG. 9 to FIG. 10 are schematic cross-sectional views of a pixel or a sub-pixel of the display panel 10. Each pixel or sub-pixel of the display panel 10 has the reflective area RA, and the reflective electrode 120 is disposed in the reflective area RA for reflecting light. The liquid crystal layer 130 may be disposed between the first alignment layer 122 and the second alignment layer 128.

As shown in FIG. 7, an ambient light LT1 or a light LT1 of the front light module can enter the display panel 10 through the substrate 124 and can be reflected by the reflective electrode 120 to form a reflected light LT2, and the reflected light LT2 can pass through the liquid crystal layer 130 and the substrate 124 and exit the display panel 10 to reach the eyes of the user. In this embodiment, the display panel 10 can be a reflective display panel or a transflective display panel, but not limited thereto.

Therefore, as shown in FIG. 7, the display panel 10 of this embodiment includes the substrate 100, the substrate 124, the liquid crystal layer 130, the thin film transistor 102, the reflective electrode 120, the first alignment layer 122 and the second alignment layer 128. The substrate 124 and the substrate 100 are oppositely disposed in the direction DR2, the liquid crystal layer 130 is disposed between the substrate 100 and the substrate 124, the thin film transistor 102 is disposed between the substrate 100 and the liquid crystal layer 130, the reflective electrode 120 is disposed between the thin film transistor 102 and the liquid crystal layer 130, the reflective electrode 120 is electrically connected to the thin film transistor 102, and the reflective electrode 120 includes the transparent conductive layer (i.e., the first patterned sub-layer 1180), the metal layer (i.e., the third patterned sub-layer 1182) and another transparent conductive layer (i.e., the second patterned sub-layer 1184). The metal layer is disposed between two transparent conductive layers, the transparent conductive layers include the indium-containing oxide, and the metal layer includes silver or silver alloy.

The display panel 10 further includes the insulating layer 104 disposed on the substrate 100 and the thin film transistor 102, and the insulating layer 104 is disposed between the reflective electrode 120 and the substrate 100. The insulating layer 104 includes the via hole 106, and the reflective electrode 120 is filled in the via hole 106 and electrically connected to the thin film transistor 102.

The first alignment layer 122 is disposed between the liquid crystal layer 130 and the reflective electrode 120. The second alignment layer 128 is disposed between the substrate 124 and the liquid crystal layer 130. The display panel 10 further includes the common electrode 126 disposed between the substrate 124 and the second alignment layer 128.

The etching solution and the manufacturing method of the display panel of the present invention are not limited to the aforementioned embodiment. The following description continues to detail other embodiments. To simplify the description and show the difference between other embodiments and the above-mentioned embodiment, identical components in each of the following embodiments are marked with identical symbols, and the identical features will not be redundantly described.

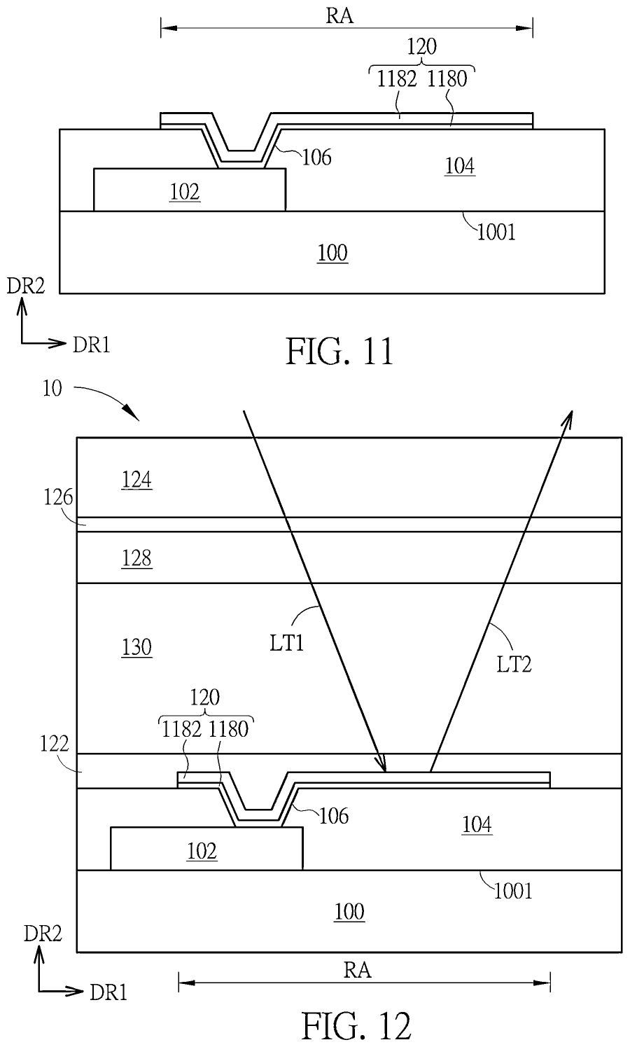

Referring to FIG. 11 and FIG. 12, FIG. 11 is a schematic diagram illustrating a step of removing a second patterned sub-layer in a manufacturing method of a display panel according to a second embodiment of the present invention, and FIG. 12 is a schematic cross-sectional diagram illustrating the display panel according to the second embodiment of the present invention. Different from the first embodiment, after the etching process 114 in FIG. 2 is performed to form the patterned conductive layer stack 116 of FIG. 5 and the photoresist pattern 112 is removed, the second patterned sub-layer 1184 of the patterned conductive layer stack 116 can be removed to form the reflective electrode 120 in this embodiment. The reflective electrode 120 of this embodiment includes the first patterned sub-layer 1180 and the third patterned sub-layer 1182 but does not include the second patterned sub-layer 1184. In some embodiments, the method of removing the second patterned sub-layer 1184 may include, but is not limited to, removing the second patterned sub-layer 1184 by an etching solution including oxalic acid.

Accordingly, the third patterned sub-layer 1182 in the reflective electrode 120 can be exposed and not covered by the second patterned sub-layer 1184. Next, as shown in FIG. 12, the first alignment layer 122 is formed on the third patterned sub-layer 1182 within a specific time after the second patterned sub-layer 1184 is removed, thereby preventing the exposed surface of the third patterned sub-layer 1182 from reacting with external substances and resulting in the decrease of reflectivity and the increase of the value of b* in CIE L*a*b* color model. Therefore, in this embodiment, the first alignment layer 122 covers the third patterned sub-layer 1182 and is directly contacted with the third patterned sub-layer 1182.

In this embodiment, the patterning process can be performed in the presence of the second sub-layer 1104, that is, the patterning process can be performed on the conductive layer stack 108 including the first sub-layer 1100, the second sub-layer 1104 and the third sub-layer 1102. In addition, the second patterned sub-layer 1184 can be removed after the patterning process to increase the reflectivity of the reflective electrode 120 and reduce the value of b* in CIE L*a*b* color model.

Therefore, the silver in the third sub-layer 1102 and the third patterned sub-layer 1182 can be protected from reacting with the external substances before the second patterned sub-layer 1184 is removed, and the reflective electrode 120 of the display panel 10 can have a better reflectivity and a lower value of b* (which can reduce the phenomenon of yellowing image) after the second patterned sub-layer 1184 is removed, thereby improving the image quality of the display panel 10.

In this embodiment, the time from the removal of the second patterned sub-layer 1184 to the formation of the first alignment layer 122 on the third patterned sub-layer 1182 is less than or equal to twenty-one hours, and preferably less than or equal to twelve hours. Since the exposed surface of the third patterned sub-layer 1182 is easy to react with the external substances, the reflectivity of the reflective electrode 120 will be lower and the value of b* of the reflective electrode 120 will be higher (i.e., the image may be yellower) as the third patterned sub-layer 1182 is exposed for a longer time. Therefore, it is necessary to perform the subsequent process (such as disposing the first alignment layer 122) within the specific time after the second patterned sub-layer 1184 is removed, and the specific time is less than or equal to twenty-one hours, and preferably less than or equal to twelve hours.

In this embodiment, the process of removing the second patterned sub-layer 1184 to form the reflective electrode 120 does not need to use a mask, thus the cost of the process can be reduced, but not limited thereto. For example, the second patterned sub-layer 1184 can be removed (for example, the second patterned sub-layer 1184 can be removed by the etching solution including oxalic acid) after the patterning process in the step S107 is performed and the photoresist pattern 112 is removed.

In other embodiments, the process of removing the second patterned sub-layer 1184 to form the reflective electrode 120 may use a mask, but not limited thereto. For example, a photoresist pattern can be formed by the mask after the patterning process in the step S107 is performed and the photoresist pattern 112 is removed, the photoresist pattern has an opening corresponding to the reflective area RA, and the second patterned sub-layer 1184 located in the reflective area RA can be removed (for example, the second patterned sub-layer 1184 located in the reflective area RA can be removed by the etching solution including oxalic acid).

In this embodiment, the steps after the first alignment layer 122 is formed can be the same as those in the first embodiment, and the details will not be repeated here.

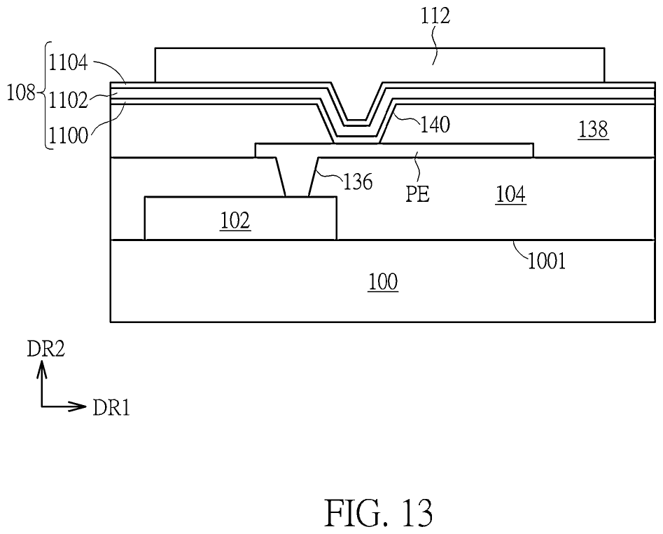

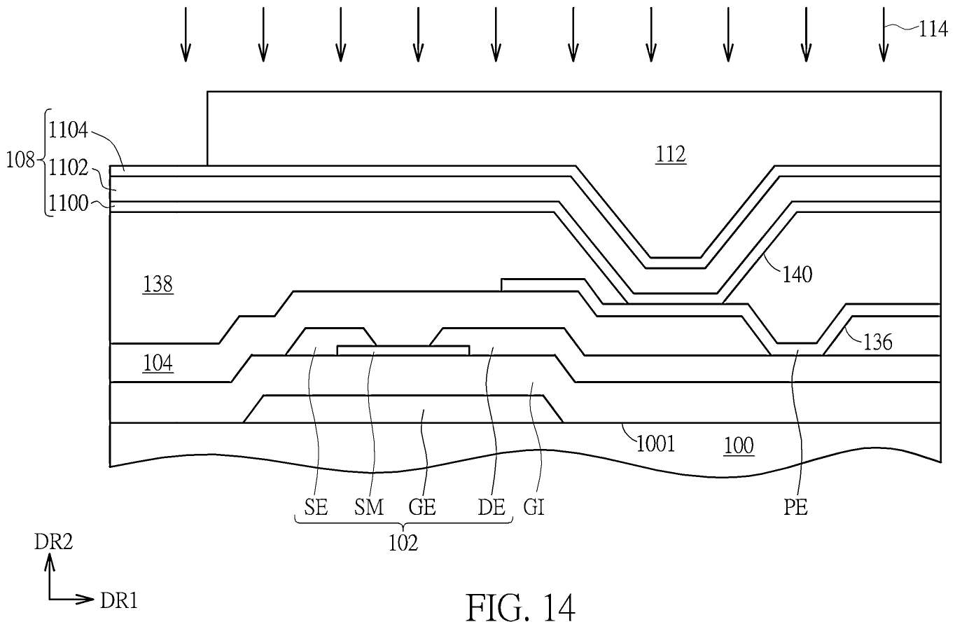

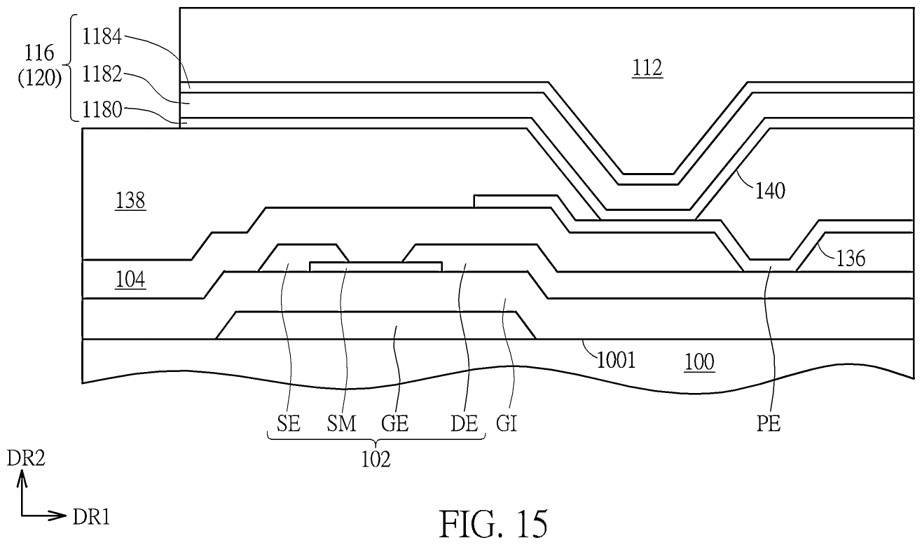

Referring to FIG. 13 to FIG. 15, FIG. 13 is a schematic diagram illustrating a step of forming a photoresist pattern in a manufacturing method of a display panel according to a third embodiment of the present invention, and FIG. 14 and FIG. 15 are schematic diagrams of an example of forming a reflective electrode in the third embodiment of the present invention.

As shown in FIG. 13, the difference between the first embodiment and this embodiment is that a via hole 136 is formed in the insulating layer 104 after the insulating layer 104 is formed. Next, a pixel electrode PE is formed on the insulating layer 104, and the pixel electrode PE is filled in the via hole 136 and is electrically connected to the thin film transistor 102. The pixel electrode PE includes a transparent conductive material, such as indium tin oxide or indium zinc oxide, but not limited thereto.

Next, an insulating layer 138 is formed on the insulating layer 104 and the pixel electrode PE, and the insulating layer 138 covers the pixel electrode PE. The insulating layer 138 may include an inorganic insulating material, an organic insulating material, or a combination of the above, but not limited thereto. In addition, a via hole 140 is formed in the insulating layer 138.

Next, the conductive layer stack 108 is formed on the insulating layer 138, and the conductive layer stack 108 is filled in the via hole 140 and is electrically connected to the pixel electrode PE. The formation of the photoresist pattern 112 and the subsequent steps can refer to the first embodiment or the second embodiment, and it will not be repeated here.

As shown in FIG. 14, the thin film transistor 102 in FIG. 13 is illustrated as a bottom gate thin film transistor in FIG. 14, but not limited thereto. In other embodiments, the thin film transistor 102 in FIG. 13 may be a top gate thin film transistor. As shown in FIG. 14, in this example, the insulating layer 104 includes a via hole 136 which can pass through the insulating layer 104 and expose a portion of the surface of the drain DE, and the pixel electrode PE can be filled in the via hole 136 and electrically connected to the drain DE. For example, the pixel electrode PE may be directly contacted with the drain electrode DE.

The insulating layer 138 includes the via hole 140, the via hole 140 can pass through the insulating layer 138 and expose a portion of the surface of the pixel electrode PE, and the conductive layer stack 108 can be filled in the via hole 140 and electrically connected to the pixel electrode PE. For example, the first sub-layer 1100 in the conductive layer stack 108 may be directly contacted to the pixel electrode PE. Next, the etching process 114 is performed to form the reflective electrode 120 shown in FIG. 15.

In the above first to third embodiments, the reflective electrode 120 is located in the reflective area of the reflective display panel or the transflective display panel, and the reflective electrode 120 is used to reflect the ambient light or the light of the front light module as an example, but it is not limited thereto. In other embodiments, the reflective electrode can be disposed in the organic light emitting diode display panel and can be used to reflect the light generated by the light emitting layer of the organic light emitting diode. Therefore, the manufacturing method of the reflective electrode 120 and the etching solution used for forming the reflective electrode 120 described above can also be applied to form the reflective electrode in the organic light emitting diode display panel, and it will not be described in detail here again.

In summary, the etching solution of the present invention includes 1 to 2.6 wt % of nitric acid, 35 to 45 wt % of acetic acid, 35 to 45 wt % of phosphoric acid and the remaining amount of water based on the total weight of the etching solution. In the manufacturing method of the display panel of the present invention, the etching solution can be used to etch the conductive layer stack to form the patterned conductive layer stack. The etching process is one-step etching, and the etching process etches the first, second and third sub-layers of the conductive layer stack together to form the first, second and third patterned sub-layers of the patterned conductive layer stack. Through the etching process of the present invention, the damage of the edge of the silver layer of the patterned conductive layer stack can be effectively suppressed, and the silver residues on the edge of the patterned conductive layer stack can also be effectively suppressed. The reflective electrode at least includes the first patterned sub-layer and the third patterned sub-layer of the patterned conductive layer stack. Through the etching solution and the etching process described above, the reflection effect of the reflective electrode can be improved, and the display quality of the display panel can be improved. In some embodiments, the second patterned sub-layer may be removed. In this way, the reflectivity of the reflective electrode can be further improved, and the value of b* in CIE L*a*b* color model can be decreased and the yellowing phenomenon of the image can be mitigated, thus the image quality of the display panel can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a display panel, comprising:
providing a first substrate;
forming a conductive layer stack on the first substrate, wherein the conductive layer stack comprises:
a first sub-layer;
a second sub-layer, disposed on the first sub-layer, wherein a material of each of the first sub-layer and the second sub-layer comprises a transparent conductive material, and the transparent conductive material comprises an indium-containing oxide; and
a third sub-layer, disposed between the first sub-layer and the second sub-layer, wherein a material of the third sub-layer comprises silver or silver alloy;
forming a photoresist pattern on the conductive layer stack; and
performing an etching process on the conductive layer stack, wherein an etching solution is used in the etching process to etch the first sub-layer, the second sub-layer and the third sub-layer to form a first patterned sub-layer, a second patterned sub-layer and a third patterned sub-layer,
wherein the etching solution comprises 1 to 2.6 wt % of nitric acid, 35 to 45 wt % of acetic acid, 35 to 45 wt % of phosphoric acid and a remaining amount of water.

2. The manufacturing method of the display panel according to claim 1, wherein a temperature of the etching solution is greater than or equal to 26° C. and less than or equal to 40° C.

3. The manufacturing method of the display panel according to claim 1, wherein the display panel comprises a reflective area, and the first patterned sub-layer, the second patterned sub-layer and the third patterned sub-layer are disposed in the reflective area of the display panel.

4. The manufacturing method of the display panel according to claim 1, further comprising removing the photoresist pattern after the etching process is performed, and removing the second patterned sub-layer after the photoresist pattern is removed.

5. The manufacturing method of the display panel according to claim 4, further comprising forming a first alignment layer on the third patterned sub-layer within a specific time after the second patterned sub-layer is removed, wherein the first alignment layer is directly contacted with the third patterned sub-layer.

6. The manufacturing method of the display panel according to claim 5, wherein the specific time is less than or equal to twenty-one hours.

7. The manufacturing method of the display panel according to claim 1, wherein the indium-containing oxide comprises indium tin oxide or indium zinc oxide.

8. The manufacturing method of the display panel according to claim 1, wherein the etching process is one-step etching.

9. An etching solution used for performing an etching process on a conductive layer stack of a display panel to form a patterned conductive layer stack, comprising:
1 to 2.6 wt % of nitric acid;
35 to 45 wt % of acetic acid;
35 to 45 wt % of phosphoric acid; and
a remaining amount of water,
wherein the conductive layer stack comprises a first sub-layer, a second sub-layer and a third sub-layer, the third sub-layer is disposed between the first sub-layer and the second sub-layer, the patterned conductive layer stack comprises a first patterned sub-layer, a second patterned sub-layer and a third patterned sub-layer, and the third patterned sub-layer is disposed between the first patterned sub-layer and the second patterned sub-layer, and the etching solution is used in the etching process to etch the first sub-layer, the second sub-layer and the third sub-layer to form the first patterned sub-layer, the second patterned sub-layer and the third patterned sub-layer,
wherein each of the first sub-layer, the second sub-layer, the first patterned sub-layer and the second patterned sub-layer comprises a transparent conductive material comprising an indium-containing oxide, and each of the third sub-layer and the third patterned sub-layer comprises silver or silver alloy.

10. The etching solution according to claim 9, wherein the etching process is one-step etching.

11. The etching solution according to claim 9, wherein a temperature of the etching solution is greater than or equal to 26° C. and less than or equal to 40° C.

12. The etching solution according to claim 9, wherein the indium-containing oxide comprises indium tin oxide or indium zinc oxide.

13. The etching solution according to claim 9, wherein the display panel comprises a reflective area, and the patterned conductive layer stack is disposed in the reflective area of the display panel.
